(19) United States
(12) Patent Application Publication
(10) Pub. No.: US 2023/0262942 A1
(43) Pub. Date: Aug. 17, 2023

(54) METAL MESH, AND HEAT SPREADER

(71) Applicant: Delta Electronics, Inc., Taoyuan City (TW)

(72) Inventor: Wen-Shiang CHEN, Taoyuan City (TW)

(21) Appl. No.: 18/078,321

(22) Filed: Dec. 9, 2022

(30) Foreign Application Priority Data
Feb. 14, 2022 (CN) 202220288739.7

(51) Int. Cl. H05K 7/20

(52) U.S. Cl. CPC H05K 7/20509

(57) ABSTRACT

A metal mesh includes a plurality of metal wires, a plurality of protrusions, and a plurality of concave portions. The metal wires, which are interlaced with each other to form a mesh, have an outer peripheral reference surface. Each protrusion is protruded from the outer peripheral reference surface of the metal wire. Each concave portion is concaved from the outer peripheral reference surface of the metal wire. Each protrusion is adjacent to at least one recess. Wherein bottom surfaces of the concave portion are non-planar.

### CROSS REFERENCE TO RELATED APPLICATIONS

This Application claims priority of China Utility Model Application No. 202220288739.7, filed on Feb. 14, 2022, the entirety of which is incorporated by reference herein.

### BACKGROUND OF THE INVENTION

### Field of the Invention

The present invention relates to metal mesh, particularly a metal mesh for a heat spreader and a metal plate.

### Description of the Related Art

In recent years, the functionality of electronic elements (such as semiconductor elements) mounted in electronic devices has gradually improved, and the heat that the electronic devices generate has increased, too. Therefore, cooling has become an important issue. In addition, due to the miniaturization of the electronic device, the internal space of the electronic device has narrowed, and the space into which a heat sink is also reduced. In order to solve the problem of heat dissipation in narrow spaces, heat spreaders are widely used.

Using conventional heat spreader technology, a chamber inside the heat spreader has a working fluid. Through the evaporation and condensation of the working fluid, the heat of the heat source at the high temperature side is transferred to the low temperature side and then dissipated. When the amount of heat generated by the heat source increases, the problem is that all the working fluid in the chamber with high temperature evaporates and dries out, and then the heat dissipation effect becomes abnormal. In order to prevent the working fluid at the high temperature side from drying out, a metal mesh with a smooth surface is generally sintered and affixed to the inner surface of the chamber to improve the circulation efficiency of the working fluid. By setting the capillary structure with capillary force, the working fluid condensed into a liquid state at a low temperature side can be quickly sucked back to a high temperature side by the capillary effect, and then absorbs heat and evaporates again.

However, in the conventional heat spreader technology, the capillary ability (the ability to guide liquid) of the traditional metal mesh can no longer meet the heat dissipation requirements of current electronic devices. Therefore, how to improve the capillary ability of the metal mesh has become an important issue in the field of heat dissipation technology.

### BRIEF SUMMARY OF THE INVENTION

In order to solve the above-mentioned problems in the prior art, an embodiment of the present invention provides a metal mesh configured to be disposed in a heat spreader, wherein the metal mesh comprises a plurality of metal wires, a plurality of protrusions and a plurality of concave portions. The metal wires intersect to form a mesh shape, wherein the metal wires have an outer peripheral reference surface. Each of the protrusions is protruded from the outer peripheral reference surface. Each of the concave portions is concaved from the outer peripheral reference surface. Each of the protrusions is adjacent to at least one of the concave portions. Wherein bottom surfaces of the concave portions are non-planar.

An embodiment of the present invention provides a metal mesh configured to be disposed in a heat spreader, wherein the metal mesh comprises a plurality of metal wires and a plurality of protrusions. The metal wires intersect with each other to form a mesh shape. The protrusions are protruded from outer surfaces of the metal wires, respectively. Each of the protrusions has a height and a projected area, and the ratio of the height to the projected area is less than 3.

An embodiment of the present invention provides a metal mesh configured to be disposed in a heat spreader, wherein the metal mesh comprises a plurality of metal wires and a plurality of protrusions. The metal wires intersect with each other to form a mesh shape. The protrusions are protruded from outer surfaces of the metal wires, respectively. The arrangement density of the protrusions on the outer surfaces is 10-200 pieces/100 μm².

In some embodiments of the present invention, the protrusions have a length of 50 nm to 1000 nm, a width of 50 nm to 1000 nm, and a pitch of 1 to 3 μm.

In some embodiments of the present invention, the protrusions have a length of 10 nm to 300 nm, a width of 10 nm to 300 nm, and a pitch of less than 10 nm.

In some embodiments of the present invention, the protrusions have a length of 500 nm to 4000 nm, a width of 500 nm to 4000 nm, and a pitch of 2 to 5 μm.

In some embodiments of the present invention, the materials of the protrusions are the same as the materials of the metal wires.

In some embodiments of the present invention, the protrusions and the metal wires are integrally formed.

In some embodiments of the present invention, the arrangement region of the protrusions with the arrangement density is all outer surfaces of the metal wires.

In addition, an embodiment of the present invention provides a heat spreader, comprising an upper plate, a lower plate, a chamber, at least one reinforcement structure and at least one porous structure. The lower plate is combined with the upper plate. The chamber is located in a closed space surrounded by the upper plate and the lower plate. The reinforcement structure extends from the upper plate toward the lower plate into the chamber. The porous structure is located in the chamber, and the porous structure is the metal mesh as described in the aforementioned embodiments.

### BRIEF DESCRIPTION OF THE DRAWINGS

The present invention can be more fully understood by reading the subsequent detailed description and examples with references made to the accompanying drawings, wherein:

FIG. 1 shows an electron microscope image of a part of a metal mesh of a first embodiment of the present invention;

FIG. 2 shows an electron microscope image of a part of the metal mesh of the first embodiment of the present invention, wherein the magnification of FIG. 2 is larger than that of FIG. 1;

FIG. 3 shows an electron microscope image of a part of the metal mesh of the first embodiment of the present invention, wherein the magnification of FIG. 3 is much larger than that of FIG. 2;

FIG. 4 shows a conceptual diagram of the metal wire of the first embodiment of the present invention before the protrusions are formed;

FIG. 5 shows a conceptual diagram of the metal wire of FIG. 4 after the protrusion is formed;

FIG. 6 shows an electron microscope image of a part of a metal mesh of a second embodiment of the present invention;

FIG. 7 shows an electron microscope image of a part of the metal mesh of the second embodiment of the present invention, wherein the magnification of FIG. 7 is larger than that of FIG. 6;

FIG. 8 shows an electron microscope image of a part of the metal mesh of the second embodiment of the present invention, wherein the magnification of FIG. 8 is much larger than that of FIG. 7;

FIG. 9 shows an electron microscope image of a part of a metal mesh of a third embodiment of the present invention;

FIG. 10 shows an electron microscope image of a part of the metal mesh of the third embodiment of the present invention, wherein the magnification of FIG. 10 is larger than that of FIG. 9;

FIG. 11 shows an electron microscope image of a part of the metal mesh of the third embodiment of the present invention, wherein the magnification of FIG. 11 is much larger than that of FIG. 10; and

FIG. 12 shows an internal cross-sectional view of a heat spreader using a metal mesh of an embodiment of the present invention.

### DETAILED DESCRIPTION OF THE INVENTION

The exemplary embodiments set forth herein are used merely for the purpose of understanding the present invention, and the inventive concept may be embodied in various forms without being limited to those exemplary embodiments. The use of like and/or corresponding numerals in the drawings of different embodiments may not necessarily suggest any correlation between different embodiments.

Unless defined otherwise, all technical and scientific terms used herein have the same meaning as commonly understood by one of ordinary skill in the art to which this invention belongs. It should be appreciated that each term, which is defined in a commonly used dictionary, should be interpreted as having a meaning conforming to the relative skills and the background or the context of the present disclosure, and should not be interpreted in an idealized or overly formal manner unless defined otherwise.

Furthermore, the phrase “in a range between a first value and a second value” or “in a range from a first value to a second value” indicates that the range includes the first value, the second value, and other values between them.

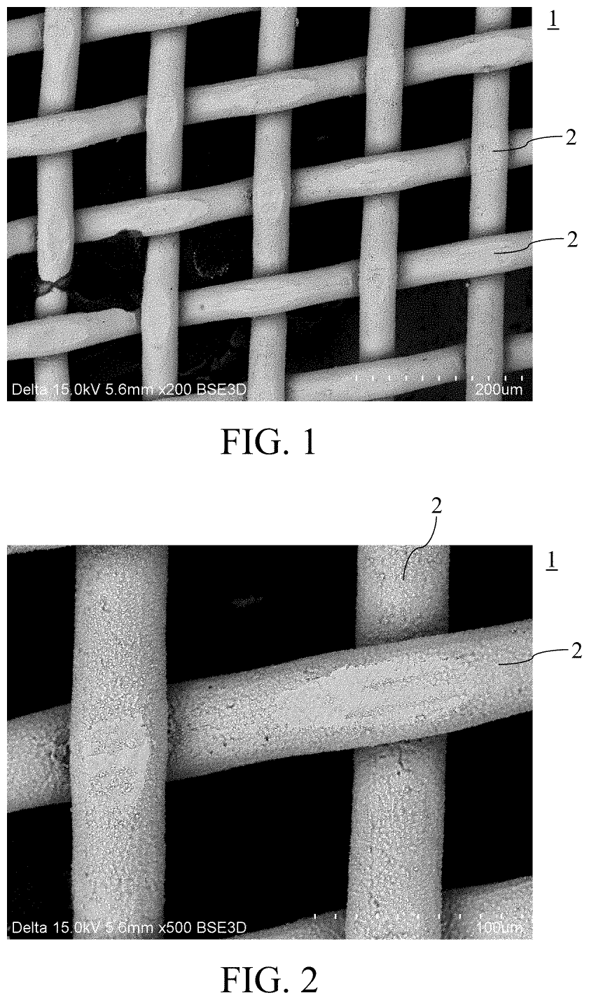

First, please refer to FIGS. 1 to 3. FIGS. 1 to 3 are electron microscope images of a part of a metal mesh 1 according to the first embodiment of the present invention. As shown in FIGS. 1 and 2, the metal mesh 1 of the first embodiment has a plurality of metal wires 2, and the metal wires 2 are intersected to form a web shape structure. In an embodiment, the metal wires 2 may be intersected with each other to form a plain weave structure, but the present invention is not limited to this, and other weave structures such as a twill weave structure may also be formed. In addition, the metal mesh 1 may be changed to a metal plate such as a copper foil or a metal sheet as required.

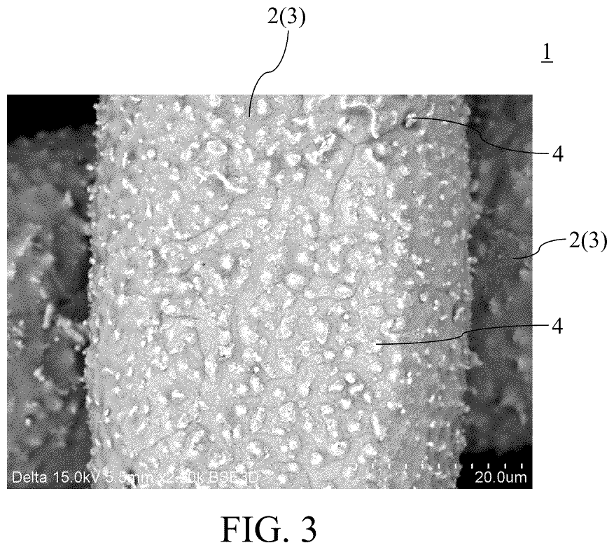

As shown in FIG. 3, a plurality of irregular protrusions 4 are formed on outer surfaces 3 of the metal wires 2 of the metal mesh 1, and the protrusions 4 are marked with white color in the figure. In the first embodiment, the protrusions 4 have a length of 50 nm to 1000 nm, a width of 50 nm to 1000 nm, and a pitch of 1 to 3 μm. Here, the length and width are the length and width of the protrusions 4 when the protrusions 4 are viewed from a top view, and the pitch is the closest distance between the outer peripheral surfaces of the two protrusions 4. In addition, the shape of the protrusion 4 may be a column shape with a small upper portion and a large lower portion, a column shape with a middle section smaller than the upper and lower portions, or a column shape of equal width at all portion.

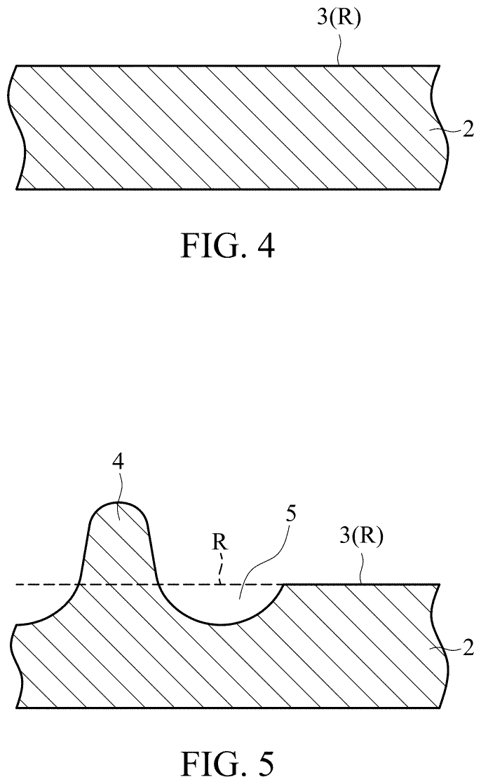

Please refer to FIGS. 4 and 5. FIG. 4 is a conceptual diagram of the metal wire 2 of the metal mesh 1 of the first embodiment of the present invention before the protrusions 4 are formed, and FIG. 5 is a conceptual diagram of the metal wire of FIG. 4 after the protrusions 4 are formed. As shown in FIG. 4, the metal wire 2 has an outer peripheral reference surface R, and the outer peripheral reference surface R is a virtual plane. Before the metal wire 2 is processed to form the protrusions 4, the outer peripheral reference surface R is the outer surface of the metal wire 2.

Regarding the processing method of the protrusions 4, for example, dry oxidation, wet oxidation, dry etching, wet etching, electroplating, immersion chemical method, etc. may be used to form a plurality of protrusions 4 on metal wires.

Next, after the metal wire 2 is processed, a plurality of protrusions 4 and a plurality of concave portions 5 are formed. In FIG. 5, the other protrusions 4 are omitted from illustration, and only one protrusion 4 is used for illustration. As shown in FIG. 5, the protrusion 4 is protruded from the outer peripheral reference surface R of the metal wire 2, and the concave portion 5 is concaved from the outer peripheral reference surface R of the metal wire 2, wherein the protrusion 4 is adjacent to at least one concave portion 5. In addition, the shape of the protrusion 4 is not limited to the one shown in FIG. 5, and may also be a column shape with a small upper portion and a large lower portion, a column shape with a middle section smaller than the upper and lower portions, or a column shape of equal width at all portion.

In addition, as shown in FIG. 5, the bottom surface of the concave portion 5 is a non-planar arc surface, but the present invention is not limited to this. A concave lower than the outer peripheral reference surface R or a concave lower than the root of the protrusion 4 may be used.

In a modification, the ratio of the height of the protrusions 4 to the projected area of the protrusions 4 may be further limited, for example, the ratio of the height of the protrusions 4 to the projected area of the protrusions is less than 3, thereby the nanostructure with better ability to guide liquid may be formed.

As shown in detail in FIG. 5, the protrusion 4 protrudes from the outer surface 3 of the metal wire 2. The height of the protrusion 4 is the distance between the root and the top of the protrusion 4, but the present invention is not limited to this. For example, a length that the protrusion 4 is protruded above the outer peripheral reference surface R may also be used as the height of the protrusion 4.

The preferably projected area of the protrusions 4 is the entire area when the protrusions 4 are viewed from a top view. However, the present invention is not limited to this. For example, the area of the horizontal section at any height of the protrusion 4 may be used as the projected area.

In addition, in a modification, the arrangement density of the protrusions 4 on the outer surface 3 may be further limited. For example, the density may be 10-200 pieces/100 μm², whereby the nanostructure with better ability to guide liquid may be formed on the metal mesh 1.

In a modification, it is preferable that the arrangement range of the protrusions 4 with the above arrangement density is all the outer surfaces of each metal wire 2. Thereby, the nanostructure with better ability to guide liquid may be formed on all regions of the metal mesh 1.

In addition, in a modification, the material of the protrusion 4 is preferably the same as the material of the metal wire 2. For example, the protrusions 4 and the metal wires 2 may also be made of copper.

In addition, in a modification, it is preferable that the protrusions 4 and the metal wires 2 are integrally formed. For example, the protrusions 4 may be formed on the metal wire 2 by using the material of the metal wire 2 itself by means of a dry oxidation method or the like. Alternatively, the protrusions 4 may be formed by trimming the shape of the outer surface 3 of the metal wire 2 by dry etching or the like. In this way, the strength of the protrusions 4 may be ensured to be strong enough, and the good bonding between the protrusions 4 and the metal wire 2 which is a metal base may also be ensured.

By forming the above-mentioned protrusions 4 on the outer surfaces 3 of the metal wires 2 of the metal mesh 1, the original smooth surface of the metal wire 2 is processed into a nano-scale three-dimensional convex structure, and the surface area of the metal wire 2 is greatly increased by hundreds to thousands of times. The portions where the protrusions 4 are formed to have stronger ability to guide liquid, the capillary ability tof the whole metal mesh 1 to guide liquid may be effectively improved without changing the mesh size of the metal mesh, so that the problems of high production cost and strength reduction caused by increasing the density of the mesh may be avoided.

Next, please refer to FIGS. 6 to 8. FIGS. 6 to 8 are electron microscope images of a part of a metal mesh 1′ of a second embodiment of the present invention. The major difference between the second embodiment and the first embodiment is that the size and distribution of the protrusions 4′ are different. The repeated parts with the first embodiment will not be described.

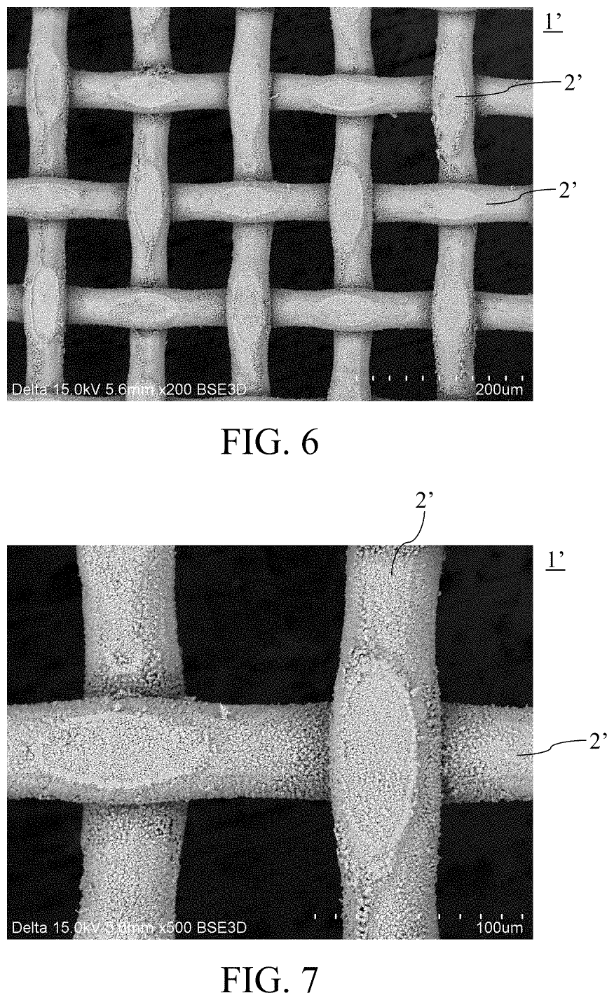

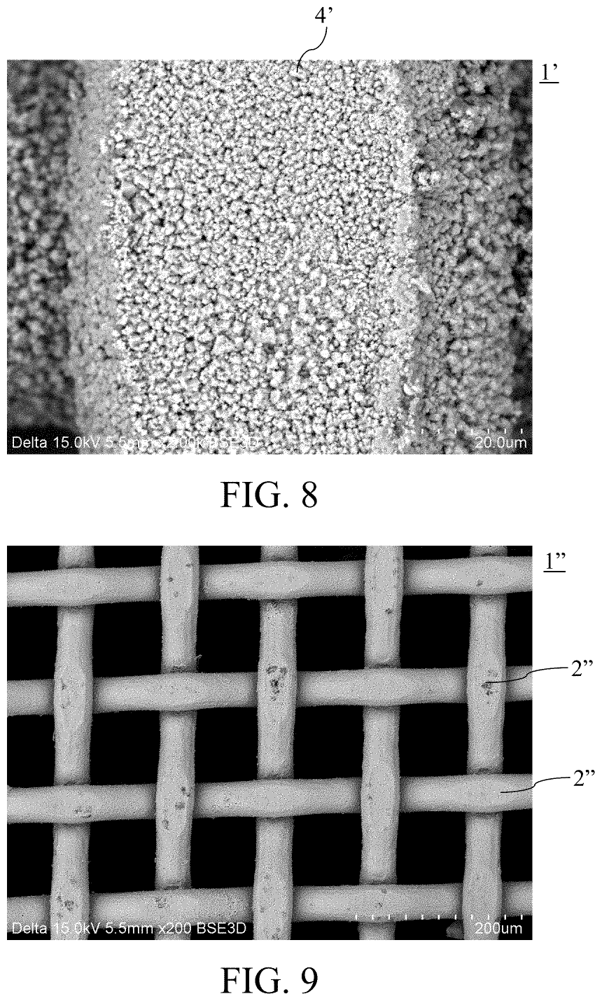

As shown in FIG. 8, a plurality of protrusions 4′ are formed on the outer surfaces of the metal wires 2′, respectively, and the protrusions 4′ are shown in FIGS. 6 and 7 are also visible in white dots in the figure. The protrusions 4′ cannot indicated clearly since of the density. In the second embodiment, the protrusions 4′ have a length of 10 nm to 300 nm, a width of 10 nm to 300 nm, and a pitch of less than 10 nm. The length and width are the length and width of the protrusion 4′ when viewed from a top view, and the distance is the closest distance between the outer peripheral surfaces of the two protrusions 4′.

Next, please refer to FIGS. 9 to 11. FIGS. 9 to 11 are electron microscope images of a part of the metal mesh 1″ of the third embodiment of the present invention. The major difference between the third embodiment and the first and second embodiments is that the size and distribution of the protrusions 4″ are different. The repeated parts with the first and second embodiments will not be described.

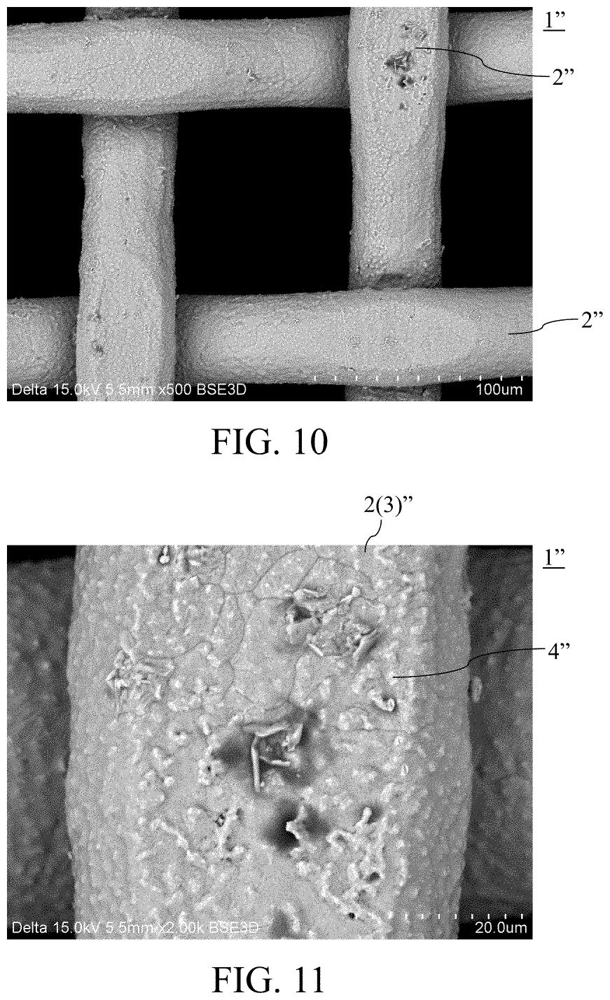

As shown in FIG. 11, a plurality of protrusions 4″ are formed on the outer surfaces 3″ of the metal wires 2″, and the protrusions 4″ are shown as white dots in FIGS. 9 and 10. In the third embodiment, the protrusions 4″ have a length of 500 nm to 4000 nm, a width of 500 nm to 4000 nm, and a pitch of 2 to 5 μm. The length and width are the length and width of the protrusion 4″ when the protrusion 4″ is viewed from a top view, and the distance is the closest distance between the outer peripheral surfaces of the two protrusions 4″.

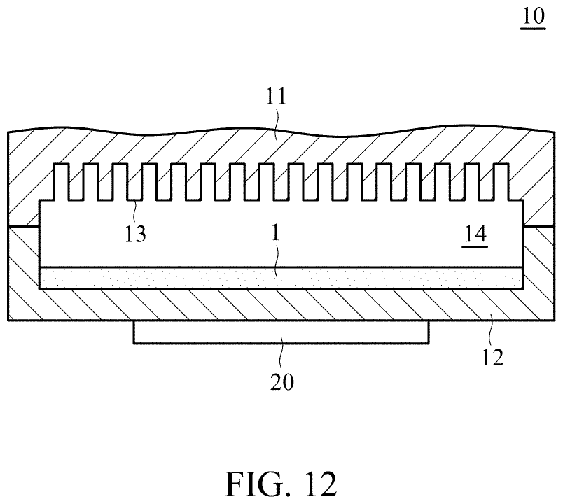

Next, please refer to FIG. 12. FIG. 12 is an internal cross-sectional view of the heat spreader 10 using the metal mesh 1 of an embodiment of the present invention. As shown in FIG. 12, the heat spreader 10 includes an upper plate 11, a lower plate 12, a reinforcement structure 13, a chamber 14 and a metal mesh 1. The upper plate 11 and the lower plate 12 may be combined to define a closed space. The chamber 14 is located in the closed space, and the reinforcement structure 13 extends from the upper plate 11 toward the lower plate 12 into the chamber 14. The working fluid is set in the chamber 14, and repeats the cycle of being evaporated at the high temperature end by the heat of the heat source 20, condensed at the low temperature end, and reabsorbed back to the high temperature end by the capillary effect of the metal mesh 1. The metal mesh 1 is provided on the inner surface of the lower plate 12 in the chamber 14. When the metal mesh 1 is not pressed against by the reinforcement structure 13, the metal mesh 1 is allowed to move within the heat spreader 10. In addition, when the metal mesh 1 is clamped by the reinforcing structure 13 and the lower plate 12, the metal mesh 1 will be fixed in the heat spreader 10. The reinforcement structures 13 are, for example, grooves or pillars.

It should be noted that the conventional metal mesh is fixed on the inner surface of the heat spreader, the inner surface of the upper plate or the inner surface of the lower plate, by sintering or welding due to the limitation of its own ability to guide liquid function. However, the nanostructure formed by the protrusions 4 of the metal mesh 1 of the present invention is a liquid-guiding structure with excellent ability to guide liquid at microscopic view, which greatly improves the ability to guide liquid of the metal mesh 1. Therefore, the metal mesh 1 of the present invention does not need to be sintered or welded to the inner surface of the heat spreader 10, and even if it is directly placed in the heat spreader 10 for use, it may exert good ability to guide liquid.

In summary, in the present invention, a plurality of protrusions are formed on the metal wire of the metal mesh by the above method, thereby improving the capillary ability of the metal mesh, thereby effectively enhancing the heat dissipation capability of the heat spreader.

Although the present invention is disclosed in the foregoing embodiments, it is not intended to limit the present invention. Those with ordinary knowledge in the technical field to which the present invention pertains may make some changes and modifications without departing from the spirit and scope of the present invention. Therefore, the scope of protection of this new model should be determined by the scope of the appended patent application.

While the invention has been described by way of example and in terms of the preferred embodiments, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements

1. A metal mesh, configured to be disposed in a heat spreader, wherein the metal mesh comprises:
a plurality of metal wires, intersecting to form a mesh shape, wherein the metal wires have an outer peripheral reference surface;
a plurality of protrusions, protruded from the outer peripheral reference surface, respectively; and
a plurality of concave portions, concaved from the outer peripheral reference surface, respectively;
wherein each of the protrusions is adjacent to at least one of the concave portions;
wherein bottom surfaces of the plurality of concave portions are non-planar.

2. A metal mesh, configured to be disposed in a heat spreader, wherein the metal mesh comprises:
a plurality of metal wires, intersecting with each other to form a mesh shape; and
a plurality of protrusions, protruded from outer surfaces of the metal wires, respectively, wherein each of the protrusions has a height and a projected area, and the ratio of the height to the projected area is less than 3.

3. A metal mesh, configured to be disposed in a heat spreader, wherein the metal mesh comprises:
a plurality of metal wires, intersecting with each other to form a mesh shape; and
a plurality of protrusions, respectively protruded from outer surfaces of the metal wires;
wherein an arrangement density of the plurality of protrusions on the outer surfaces is 10-200 pieces/100 um 2.

4. The metal mesh as claimed in claim 2, wherein each of the metal wires has an outer peripheral reference surface;
each of the protrusions is adjacent to a concave portion;
wherein a bottom surface of the concave portion is non-planar and is concaved from the outer peripheral reference surface.

5. The metal mesh as claimed in claim 3, wherein each of the protrusions has a height and a projected area, and the ratio of the height to the projected area is less than 3.

6. The metal mesh as claimed in any one of claim 1, wherein the protrusions have a length of 50 nm to 1000 nm, a width of 50 nm to 1000 nm, and a pitch of 1 to 3 μm.

7. The metal mesh as claimed in any one of claim 1, wherein the protrusions have a length of 10 nm to 300 nm, a width of 10 nm to 300 nm, and a pitch of less than 10 nm.

8. The metal mesh as claimed in any one of claim 1, wherein the protrusions have a length of 500 nm to 4000 nm, a width of 500 nm to 4000 nm, and a pitch of 2 to 5 μm.

9. The metal mesh as claimed in any one of claim 1, wherein the materials of the protrusions are the same as the materials of the metal wires.

10. The metal mesh as claimed in any one of claim 1, wherein the protrusions and the metal wires are integrally formed.

11. The metal mesh as claimed in claim 3, wherein the arrangement region of the protrusions with the arrangement density is all outer surfaces of the metal wires.

12. A heat spreader comprising:
an upper plate;
a lower plate, combined with the upper plate;
a chamber, located in a closed space surrounded by the upper plate and the lower plate;
at least one reinforcement structure, extending from the upper plate toward the lower plate into the chamber: and
at least one porous structure, located in the chamber, wherein the porous structure is the metal mesh as claimed in claim 1.
